(19) United States
(12) Patent Application Publication
(10) Pub. No.: US 2024/0290669 A1
(43) Pub. Date: Aug. 29, 2024

(54) SEMICONDUCTOR STRUCTURE AND METHOD FOR MANUFACTURING THE SAME

(71) Applicant: SAMSUNG ELECTRONICS CO., LTD., Suwon-si (KR)

(72) Inventors: Sunkyoung SEO, Suwon-si (KR); Dohyun KIM, Suwon-si (KR); Yeongseon KIM, Suwon-si (KR); Juhyeon KIM, Suwon-si (KR); Hyoeun KIM, Suwon-si (KR); Jeongoh HA, Suwon-si (KR)

(73) Assignee: SAMSUNG ELECTRONICS CO., LTD., Suwon-si (KR)

(21) Appl. No.: 18/385,082

(22) Filed: Oct. 30, 2023

(30) Foreign Application Priority Data
Feb. 23, 2023 (KR) 10-2023-0024608

(51) Int. Cl. H01L 21/66; H01L 23/00; H01L 25/065; H10B 80/00

(52) U.S. Cl. CPC H01L 22/32; H01L 24/08; H01L 25/0657; H10B 80/00; H01L 2224/08145; H01L 2225/06541; H01L 2225/06582; H01L 2225/06596; H01L 2924/1436

(57) ABSTRACT

A semiconductor structure according to an embodiment may include: an interconnect structure on a substrate; an interlayer dielectric layer on the interconnect structure; a first conductive pad within the interlayer dielectric layer and electrically coupled with the interconnect structure; a second conductive pad within the interlayer dielectric layer and electrically decoupled from the interconnect structure; a first via plug within the interlayer dielectric layer; and a bonding structure on the interlayer dielectric layer and including a first bonding pad, a plurality of second bonding pads, and a bonding dielectric layer, wherein the first bonding pad is electrically coupled to the first via plug, some of the plurality of second bonding pads are spaced apart from the first conductive pad in a vertical direction, and others of the plurality of second bonding pads are spaced apart from the second conductive pad in the vertical direction.

### CROSS-REFERENCE TO RELATED APPLICATION

This application claims priority to and the benefit of Korean Patent Application No. 10-2023-0024608, filed in the Korean Intellectual Property Office on Feb. 23, 2023, the entire contents of which are incorporated herein by reference.

### BACKGROUND

### 1. Field

Embodiments of the present disclosure relate to a semiconductor structure and a manufacturing method thereof.

### 2. Description of Related Art

In a semiconductor industry field, where there is a demand for down-sized and light-weight electronic devices, semiconductor devices mounted on electronic devices that are down-sized, lightweight, and thinned, and that simultaneously have increased speed, multi-functionality, and large capacity are being sought. Therefore, a stacked-type semiconductor device (e.g., a High Bandwidth Memory (HBM) and a system in package (SIP)) formed by stacking a plurality of individual semiconductor chips to store more data and transmit data at a higher speed are being developed.

The stacked-type semiconductor device is manufactured by coupling between homogeneous or heterogeneous semiconductor chips, and what is important in coupling between the semiconductor chips is that the semiconductor chips must be coupled with a high I/O density. If the density of I/O is increased so that an electrical signal connection density becomes similar to a copper line density in a front end process, it is possible to produce a result similar to that of one semiconductor chip made through the front end process even if homogeneous or heterogeneous semiconductor chips are combined in a back end process.

As such, in order to manufacture the coupled semiconductor chips having the high I/O density, a hybrid bonding process may be applied to coupling between semiconductor chip dies. The hybrid bonding is a method of bonding two devices by fusing the same materials of the two devices by using the bonding properties of the same material. Here, the hybrid bonding means that two different types of bonding are performed, for example, the bonding of two devices with a first type of metal-metal bonding and a second type of non-metal-non-metal bonding.

The hybrid bonding is performed in a state in which bonding surfaces of semiconductor chip dies to be bonded are flattened. However, each bonding surface of the semiconductor chips may have a large surface topography deviation, resulting in a stack void at each interface between the bonding surfaces of the semiconductor chips, and a limitation in implementing a fine pitch I/O since a vertical line of the dummy test pad and the dummy bonding pad do not match. Thus, in the related art, there is a problem in applying the hybrid bonding to the coupling between the semiconductor chip dies.

Therefore, it is necessary to develop a new package technology that can solve the above problems by making the bonding surface of the semiconductor chip die flatter.

### SUMMARY

According to embodiments of the present disclosure, a semiconductor structure is provided. The semiconductor structure includes: an interconnect structure on a substrate; an interlayer dielectric layer on the interconnect structure; at least one first conductive pad within the interlayer dielectric layer and electrically coupled with the interconnect structure; at least one second conductive pad within the interlayer dielectric layer and electrically decoupled from the interconnect structure; and at least one first via plug within the interlayer dielectric layer; and a bonding structure on the interlayer dielectric layer. The bonding structure includes at least one first bonding pad, a plurality of second bonding pads, and a bonding dielectric layer, wherein the at least one first bonding pad is electrically coupled to the at least one first via plug, wherein some of the plurality of second bonding pads are spaced apart from the at least one first conductive pad in a vertical direction, and wherein others of the plurality of second bonding pads are spaced apart from the at least one second conductive pad in the vertical direction.

According to embodiments of the present disclosure, a semiconductor chip stacking structure is provided. The semiconductor chip stacking structure includes: a first semiconductor chip die; and a second semiconductor chip die bonded to the first semiconductor chip die, wherein each of the first semiconductor chip die and the second semiconductor chip die includes: an interconnect structure on a substrate; an interlayer dielectric layer on the interconnect structure; at least one first conductive pad within the interlayer dielectric layer and electrically coupled with the interconnect structure; at least one second conductive pad within the interlayer dielectric layer and electrically decoupled from the interconnect structure; at least one first via plug within the interlayer dielectric layer and electrically coupled with the interconnect structure; and a first bonding structure on the interlayer dielectric layer. The first bonding structure includes: a first dielectric layer; a second dielectric layer on the first dielectric layer; at least one first bonding pad passing through the first dielectric layer and the second dielectric layer; and a plurality of second bonding pads passing through the first dielectric layer and the second dielectric layer. The at least one first bonding pad is electrically coupled with the at least one first via plug, some of the plurality of second bonding pads are spaced apart from the at least one first conductive pad in a vertical direction, and others of the plurality of second bonding pads are spaced apart from the at least one second conductive pad in the vertical direction.

According to embodiments of the present disclosure, a semiconductor structure manufacturing method is provided. The a semiconductor structure manufacturing method includes: forming at least one test pad and at least one dummy pad on a interconnect structure on a substrate, wherein the at least one test pad is electrically coupled with the interconnect structure, and the at least one dummy pad is electrically decoupled from the interconnect structure; depositing an interlayer dielectric layer on the at least one test pad and the at least one dummy pad; depositing a bonding dielectric layer on the interlayer dielectric layer; and forming at least one via plug passing through the interlayer dielectric layer and at least one first bonding pad and a plurality of second bonding pads passing through the bonding dielectric layer, wherein the at least one first bonding pad is in contact with the at least one via plug, wherein some of the plurality of second bonding pads are spaced apart from the at least one test pad in a vertical direction, and wherein others of the plurality of second bonding pads are spaced apart from the at least one dummy pad in the vertical direction.

According to an embodiment, in the semiconductor structure, the semiconductor chip stacking structure, and the semiconductor structure manufacturing method, to planarize the bonding surface of the semiconductor chip die, the dummy conductive pads are additionally formed at the same level as the EDS test pad, at the same level as the bonding pads electrically coupled to the via plug, and at the position spaced apart in the vertical direction from the EDS test pad and the dummy conductive pad, the dummy bonding pad is additionally disposed, thereby stack voids may be prevented from occurring at interfaces between the bonding surfaces of the semiconductor chips, and the semiconductor chip I/O with a high density and a fine pitch may be implemented.

### BRIEF DESCRIPTION OF DRAWINGS

FIG. 1 is a cross-sectional view showing a semiconductor structure that may include hybrid bonding and has a fine-pitch I/O by disposing additional dummy bonding pads at positions spaced apart from a first conductive pad and second conductive pads in a vertical direction.

FIG. 2 is a cross-sectional view showing a semiconductor structure that may include hybrid bonding and has a fine-pitch I/O by additionally disposing dummy bonding pads at positions spaced apart from a first conductive pad and second conductive pads in a vertical direction, and connecting a dummy bonding pad and a second conductive pad with a via plug.

FIG. 3 is a cross-sectional view showing a step of forming a substrate, a device structure on the substrate, and an interconnect structure on the device structure, according to a semiconductor structure manufacturing method.

FIG. 4 is a cross-sectional view showing a step of depositing an interlayer dielectric layer on an interconnect structure, according to a semiconductor structure manufacturing method

FIG. 5 is a cross-sectional view showing a step of forming a photoresist pattern by depositing a photoresist on a dielectric layer and exposing and developing the photoresist, according to a semiconductor structure manufacturing method.

FIG. 6 is a cross-sectional view showing a step of etching a dielectric layer using a photoresist pattern as an etching mask, according to a semiconductor structure manufacturing method.

FIG. 7 is a cross-sectional view showing a step of removing a photoresist pattern and depositing a seed metal layer, according to a semiconductor structure manufacturing method.

FIG. 8 is a cross-sectional view showing a step of forming first conductive pads, second conductive pads, and third conductive pads by electroplating, according to a semiconductor structure manufacturing method.

FIG. 9 is a cross-sectional view showing a step of performing an EDS test on a first conductive pad, according to a semiconductor structure manufacturing method.

FIG. 10 is a cross-sectional view showing a step of depositing a metal layer on an interconnect structure, according to a semiconductor structure manufacturing method.

FIG. 11 is a cross-sectional view showing a step of forming a photoresist pattern by depositing a photoresist on a metal layer and exposing and developing the photoresist, according to a semiconductor structure manufacturing method.

FIG. 12 is a cross-sectional view showing a step of etching a metal layer by using a photoresist pattern as an etching mask, according to a semiconductor structure manufacturing method.

FIG. 13 is a cross-sectional view showing a step of removing a photoresist pattern, according to a semiconductor structure manufacturing method.

FIG. 14 is a cross-sectional view showing a step of performing an EDS test on a first conductive pad, according to a semiconductor structure manufacturing method.

FIG. 15 is a cross-sectional view showing steps of sequentially depositing an interlayer dielectric layer, an etch stop layer, a first dielectric layer, a second dielectric layer, and a third dielectric layer, according to a semiconductor structure manufacturing method.

FIG. 16 is a cross-sectional view showing a step of forming a photoresist pattern by depositing a photoresist on a third dielectric layer and exposing and developing the photoresist, according to a semiconductor structure manufacturing method.

FIG. 17 is a cross-sectional view showing a step using a photoresist pattern as an etching mask to etch an interlayer dielectric layer, an etch stop layer, a first dielectric layer, a second dielectric layer, and a third dielectric layer, according to a semiconductor structure manufacturing method.

FIG. 18 is a cross-sectional view showing a step of removing a photoresist pattern, according to a semiconductor structure manufacturing method.

FIG. 19 is a cross-sectional view showing a step of forming a photoresist pattern by depositing a photoresist on a third dielectric layer and exposing and developing the photoresist, according to a semiconductor structure manufacturing method.

FIG. 20 is a cross-sectional view showing a step of etching a first dielectric layer, a second dielectric layer, and a third dielectric layer by using a photoresist pattern as an etching mask, according to a semiconductor structure manufacturing method.

FIG. 21 is a cross-sectional view showing a step of removing a photoresist pattern and depositing a seed metal layer on an exposed surface, according to a semiconductor structure manufacturing method.

FIG. 22 is a cross-sectional view showing a step of filling through holes with a conductive material by electroplating, according to a semiconductor structure manufacturing method.

FIG. 23 is a cross-sectional view showing a semiconductor structure in which through-silicon vias are disposed in a substrate, and an external connection terminal structure is disposed on a bottom surface of a substrate in addition to a semiconductor structure of FIG. 2.

FIG. 24 is a cross-sectional view showing a semiconductor structure in which through-silicon vias are disposed in a substrate and a bonding structure capable of hybrid bonding to a bottom surface of a substrate is disposed in addition to a semiconductor structure of FIG. 2.

FIG. 25 is a cross-sectional view showing that a front side of a semiconductor structure of FIG. 2 and the front side of the semiconductor structure of FIG. 23 are bonded by hybrid bonding.

FIG. 26 is a cross-sectional view showing a Package on Package (POP) structure in which a front side of one semiconductor structure of FIG. 25 and a front side of another semiconductor structure of FIG. 25 are bonded by hybrid bonding.

FIG. 27 is a cross-sectional view showing that a front side of a semiconductor structure of FIG. 2 and a back side of a semiconductor structure of FIG. 24 are bonded by hybrid bonding.

FIG. 28 is a cross-sectional view showing a semiconductor chip stacking structure that is a high bandwidth memory (HBM) structure in which a front side of one semiconductor structure of FIG. 27 and a back side of another semiconductor structure are bonded by hybrid bonding.

### DETAILED DESCRIPTION

Hereinafter, non-limiting example embodiments of the present disclosure will be described more fully with reference to the accompanying drawings for a person of ordinary skill to easily implement embodiments of the present disclosure. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

Because the size and thickness of each configuration shown in the drawings may be arbitrarily shown for better understanding and ease of description, embodiments of the present disclosure are not limited thereto.

Throughout the specification, when it is described that a part is “connected” (or in contact with, or coupled) to another part, the part may be “directly connected” to the other element or “connected” to the other part through a third part. In addition, unless explicitly described to the contrary, the word “comprise” (or “include”), and variations such as “comprises” (or “includes”) or “comprising” (or “including”), will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” means positioned above or below the object portion, and does not necessarily mean positioned on the upper side of the object portion based on a gravitational direction.

Further, in the specification, the phrase “on a plane” means when an object portion is viewed from above, and the phrase “on a cross-section” means when a cross-section taken by vertically cutting an object portion is viewed from the side.

Hereinafter, a semiconductor structure, a semiconductor chip stacking structure, and a semiconductor structure manufacturing method of embodiments of the present disclosure will be described with reference to accompanying drawings.

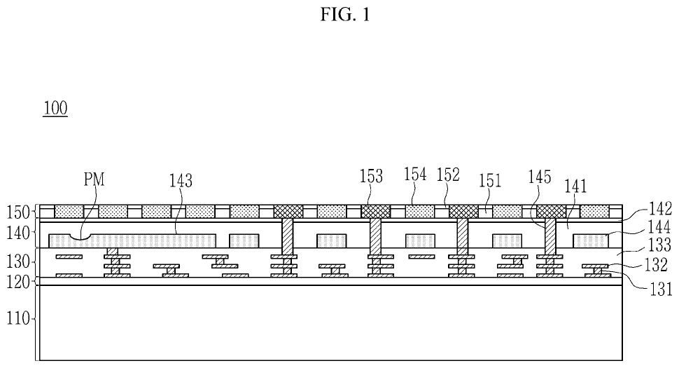

FIG. 1 is a cross-sectional view showing a semiconductor structure that may include hybrid bonding and has a fine-pitch I/O by disposing additional dummy bonding pads (e.g., second bonding pads 154) at positions spaced apart from a first conductive pad 143 and second conductive pads 144 in a vertical direction.

Referring to FIG. 1, a semiconductor chip die 100 may include a substrate 110, a device structure 120 on the substrate 110, a interconnect structure 130 on the device structure 120, an interlayer structure 140 on the interconnect structure 130, and a bonding structure 150 on the interlayer structure 140.

The substrate 110 may include silicon or other semiconductor material. In an embodiment, the substrate 110 may be doped with a P-type or N-type dopant. In another embodiment, the substrate 110 may be undoped. In an embodiment, the substrate 110 may include bulk silicon, silicon-on-insulator (SOI), a silicon substrate, silicon germanium, silicon germanium-on-insulator (SGOI), silicon carbide, indium antimonide, a lead tellurium compound, indium arsenic, indium phosphide, gallium arsenic, or gallium antimonide, but is not limited thereto.

The device structure 120 is disposed on the substrate 110. The device structure 120 is formed on the substrate 110 in a Front-End-Of-Line (FEOL) process. In an embodiment, the device structure 120 may include an active device, a passive device, or a combination thereof. In an embodiment, the device structure 120 may include a gate structure, a source region and a drain region, and shallow trench isolation (STI) structure. In an embodiment, the device structure 120 may include a transistor, a diode, a capacitor, a resistor, and the like.

The interconnect structure 130 is disposed on the device structure 120. The interconnect structure 130 is formed on the device structure 120 in Back-End-Of-Line (BEOL) process. The interconnect structure 130 may include metal lines, connecting elements, and an interlayer dielectric (ILD) material layer 133.

The metal lines may be a signal wire for transmitting a signal to each element and a power wire for transmitting power to each element. The metal lines may include contact plugs 131 and metal line layers (also referred to as metal lines) 132. The contact plugs 131 are patterned in a vertical direction to interconnect metal line layers 132 to transmit signal and power between different level layers. The metal line layers 132 are patterned in a horizontal direction to transfer signal and power between the same level layers.

In an embodiment, the contact plugs 131 and the metal line layers 132 may include at least one of: copper, aluminum, tungsten, nickel, gold, tin, titanium, and alloys thereof. In another embodiment, the metal lines include fewer or more contact plugs 131 and metal line layers 132.

The interlayer dielectric material layer 133 fills and insulates the contact plugs 131 and the metal line layers 132. In an embodiment, the interlayer dielectric material layer 133 may include a silicon oxide, a silicon nitride, a silicon acid nitride, a tetraethyl orthosilicate (TEOS)-forming oxide, phosphosilicate glass (PSG), borophosphosilicate glass (BPSG), a low-k dielectric material, another suitable dielectric material, or a combination thereof.

The interlayer structure 140 is disposed on the interconnect structure 130. The interlayer structure 140 is formed on a interconnect structure 130 in a BEOL process. The interlayer structure 140 may include an interlayer dielectric layer 141, an etch stop layer 142, a first conductive pad 143, second conductive pads 144, and via plugs 145.

The interlayer dielectric layer 141 fills around and insulates the first conductive pad 143, the second conductive pads 144, and the via plugs 145. In an embodiment, the interlayer dielectric layer 141 may include a silicon oxide, a silicon nitride, a silicon oxynitride, a TEOS-forming oxide, PSG, BPSG, a low-k dielectric material, another suitable dielectric material, or a combination thereof.

An etch stop layer 142 is disposed on the interlayer dielectric layer 141. In an embodiment, the etch stop layer 142 may include silicon nitride. In an embodiment, the etch stop layer 142 may include SiN, SiCN, or SiON.

The first conductive pad 143 may include an electrical die sorting (EDS) test pad. The EDS test corresponds to a process of sending electricity by contacting a probe card to the EDS test pad and selecting whether it is a defective chip through the signal. A probe mark PM is formed on the upper surface of the first conductive pad 143, and the probe mark PM may have a shape of a recess portion. The first conductive pad 143 is electrically coupled with the interconnect structure 130. In an embodiment, the width of the first conductive pad 143 in the horizontal direction may be about 0.01 μm to about 10 μm. In an embodiment, the depth of the first conductive pad 143 in the vertical direction may be about 0.1 μm to about 7 μm.

The second conductive pads 144 are disposed at the same level as a level of the first conductive pad 143. The second conductive pads 144 may be formed simultaneously when the first conductive pad 143 is formed. The second conductive pads 144 may include a dummy conductive pad. The second conductive pads 144 are electrically decoupled from the interconnect structure 130. In an embodiment, the depth of the second conductive pad 144 in the vertical direction may be about 0.1 μm to about 7 μm. In an embodiment, the interval between the second conductive pads 144 may be about 30 μm or less.

When the first conductive pad 143 is formed by the electroplating process, the uniformity of the electroplating may be improved by additionally forming the dummy conductive pads (the second conductive pads 144) around the via plugs 145. In addition, by forming the dummy conductive pads (the second conductive pads 144) at the same level as the level of the first conductive pad 143, the flatness may be increased in the subsequent chemical mechanical polishing (CMP) process.

In order to implement the fine pitch I/O, improve the uniformity of the electroplating, and increase the flatness in the chemical mechanical polishing (CMP) process, the number and size of the second conductive pads 144 may be adjusted to adjust the local metal ratio within the interlayer structure 140. Accordingly, the second conductive pad 144 may have various sizes.

The via plugs 145 pass through the interlayer dielectric layer 141 and the etch stop layer 142. One end of the via plug 145 is in contact with the interconnect structure 130 and the other end is in contact with the first bonding pad 153. The via plugs 145 are electrically coupled with the interconnect structure 130. In an embodiment, the width of the via plug 145 in the horizontal direction may be about 0.01 μm to about 10 μm. In an embodiment, the depth of the via plug 145 in the vertical direction may be about 0.01 μm to about 10 μm.

In an embodiment, the first conductive pads 143, the second conductive pads 144, and the via plugs 145 may include at least one of copper, aluminum, tungsten, nickel, gold, tin, titanium, and alloys thereof. In another embodiment, the metal line may include fewer or more first conductive pads 143, second conductive pads 144, and via plugs 145.

The bonding structure 150 is disposed on the interlayer structure 140. The bonding structure 150 may include a first dielectric layer 151, a second dielectric layer 152, a first bonding pad 153, and a second bonding pad 154.

The first dielectric layer 151 is disposed on the etch stop layer 142. In an embodiment, the first dielectric layer 151 may include a silicon oxide, a TEOS-forming oxide, another suitable dielectric material, or a combination thereof. In an embodiment, the thickness of the first dielectric layer 151 in the vertical direction may be about 0.1 μm to about 7 μm.

The second dielectric layer 152 is disposed on the first dielectric layer 151. The second dielectric layer 152 is a layer on which a non-metal-non-metal hybrid bonding is performed with a dielectric layer of another semiconductor chip die. In an embodiment, the second dielectric layer 152 may include a silicon nitride. In an embodiment, the second dielectric layer 152 may include SiN or SiCN. In an embodiment, the thickness of the second dielectric layer 152 in the vertical direction may be about 0.1 μm.

The first bonding pads 153 are disposed to pass through the first dielectric layer 151 and the second dielectric layer 152. The first bonding pads 153, together with the second bonding pads 154, are pads on which the metal-metal hybrid bonding is performed with bonding pads of other semiconductor chip dies, whereby electrical coupling is performed between the semiconductor chip dies and the semiconductor chip dies. The first bonding pad 153 is electrically coupled to the via plug 145. In an embodiment, the width of the first bonding pads 153 in the horizontal direction may be about 0.01 μm to about 10 μm. In an embodiment, the depth of the first bonding pads 153 in the vertical direction may be about 0.1 μm to about 7 μm.

The second bonding pads 154 are disposed to pass through the first dielectric layer 151 and the second dielectric layer 152. The second bonding pads 154 are disposed at the same level as the level of the first bonding pads 153. The second bonding pad 154 may include a dummy bonding pad. The second bonding pads 154 are pads on which the metal-metal hybrid bonding is performed with bonding pads of other semiconductor chip dies together with the first bonding pads 153, but are not related to electrical coupling between the semiconductor chip dies and the semiconductor chip dies. The second bonding pad 154 is electrically decoupled from the interconnect structure 130 or other components. In an embodiment, the width of the second bonding pads 154 in the horizontal direction may be about 0.01 μm to about 10 μm. In an embodiment, the depth of the second bonding pads 154 in the vertical direction may be about 0.1 μm to about 7 μm. In an embodiment, the interval between the first bonding pads 153, between the second bonding pads 154, or between the first bonding pad 153 and the second bonding pad 154 may be about 30 μm or less.

The second bonding pad 154 is disposed on the first conductive pad 143 or the second conductive pad 144. The second bonding pad 154 is disposed to be spaced apart from the first conductive pad 143 or the second conductive pad 144 in the vertical direction. The second bonding pad 154 is not physically or electrically connected to the first conductive pad 143 or the second conductive pad 144. At least one second bonding pad 154 may be disposed on the first conductive pad 143 or the second conductive pad 144. In an embodiment, the footprint of the second bonding pad 154 may be positioned within the footprint of the first conductive pad 143 or the footprint of the second conductive pad 144, but is not limited thereto.

The first bonding pad 153 or the second bonding pad 154 may have the same diameter as another first bonding pad 153 or another second bonding pad 154. The interval (pitch) between the adjacent first bonding pads 153, the interval between the adjacent second bonding pads 154, or the interval between the adjacent first bonding pads 153 and second bonding pad 154 may be the same. In an embodiment, in a plan view, the first bonding pad 153 or the second bonding pad 154 may include a circle, an ellipse, a quadrangle, a polygon, and various other shapes. In an embodiment, the first bonding pad 153 and the second bonding pad 154 may include copper. In another embodiment, the first bonding pad 153 and the second bonding pad 154 may be a metallic material capable of performing hybrid bonding.

In an embodiment, the second conductive pads 144 and the second bonding pads 154 may have the same interval (Pitch). In another embodiment, the second conductive pads 144 and the second bonding pads 154 may have different intervals. In an embodiment, the second conductive pad 144 and the second bonding pad 154 may have the same shape and size as each other. In another embodiment, the second conductive pad 144 and the second bonding pad 154 may have different shapes and sizes.

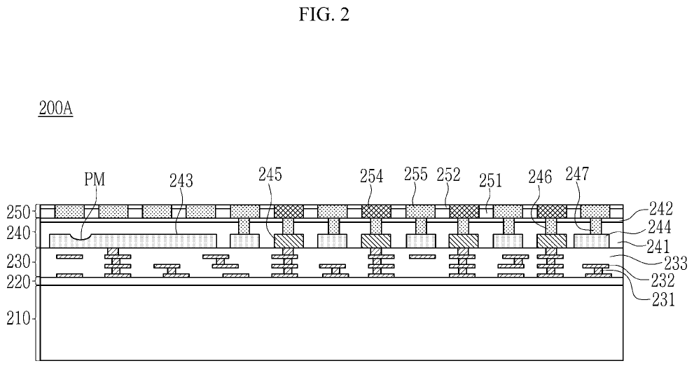

FIG. 2 is a cross-sectional view showing a semiconductor structure that may include hybrid bonding and has a fine-pitch I/O by additionally disposing dummy bonding pads (e.g., second bonding pads 255) at positions spaced apart from a first conductive pad 243 and second conductive pads 244 in a vertical direction, and connecting a second bonding pad 255 and second conductive pad 244 with a via plug.

Referring to FIG. 2, a semiconductor chip die 200A may include a substrate 210, a device structure 220 on the substrate 210, an interconnect structure 230 on the device structure 220, an interlayer structure 240 on the interconnect structure 230, and a bonding structure 250 on the interlayer structure 240.

The contents described for the substrate 110, the device structure 120, the interconnect structure 130, and the bonding structure 150 of the semiconductor chip die 100 of FIG. 1 may be equally applied to the substrate 210, the device structure 220, the interconnect structure 230, and the bonding structure 250 of the semiconductor chip die 200A.

The interlayer structure 240 is disposed on the interconnect structure 230. The interlayer structure 240 is formed on the interconnect structure 230 in the BEOL process. The interlayer structure 240 may include an interlayer dielectric layer (ILD) 241, an etch stop layer 242, a first conductive pad 243, second conductive pads 244, third conductive pads 245, first via plugs 246, and second via plugs 247. The interconnect structure 230 may include metal lines, connecting elements, and an interlayer dielectric (ILD) material layer 233. The metal lines may include contact plugs 231 and metal line layers 232.

The interlayer dielectric layer (ILD) 241 fills around and insulates the first conductive pad 243, the second conductive pads 244, the third conductive pads 245, the first via plugs 246, and the second via plugs 247. In an embodiment, the interlayer dielectric layer (ILD) 241 may include a silicon oxide, a silicon nitride, a silicon oxynitride, a TEOS-forming oxide, PSG, BPSG, a low-k dielectric material, another suitable dielectric material, or a combination thereof.

The etch stop layer 242 is disposed on the interlayer dielectric layer (ILD) 241. In an embodiment, the etch stop layer 242 may include a silicon nitride. In an embodiment, the etch stop layer 242 may include SIN, SiCN, or SiON.

The first conductive pad 243 may include an EDS test pad. The probe mark PM is formed on the upper surface of the first conductive pad 243, and the probe mark PM may have a shape of a recess portion. The first conductive pad 243 is electrically coupled with the interconnect structure 230. In an embodiment, the width of the first conductive pad 243 in the horizontal direction may be about 20 μm to about 60 μm. In an embodiment, the depth of the first conductive pad 243 in the vertical direction may be about 0.1 μm to about 7 μm.

The second conductive pads 244 are disposed on the same level as a level of the first conductive pad 243. The second conductive pads 244 may be formed simultaneously when forming the first conductive pad 243. The second conductive pads 244 may include a dummy conductive pad. The second conductive pads 244 are electrically decoupled from the interconnect structure 230. In an embodiment, the width of the second conductive pad 244 in the horizontal direction may be about 0.01 μm to about 10 μm. In an embodiment, the depth of the second conductive pad 244 in the vertical direction may be about 0.1 μm to about 7 μm.

The third conductive pads 245 are disposed on the same level as the level of the first conductive pad 243. The third conductive pads 245 may be formed simultaneously when the first conductive pad 243 is formed. The third conductive pads 245 are electrically coupled with the first via plug 246 connected to the first bonding pad 254 and the interconnect structure 230. In an embodiment, the width of the third conductive pad 245 in the horizontal direction may be about 0.01 μm to about 10 μm. In an embodiment, the depth of the third conductive pad 245 in the vertical direction may be about 0.1 μm to about 7 μm. In an embodiment, the interval between the second conductive pads 244, between the third conductive pads 245, or between the second conductive pad 244 and the third conductive pad 245 may be about 30 μm or less.

Compared to the semiconductor chip die 100 of FIG. 1, the semiconductor chip die 200A of FIG. 2 further includes third conductive pads 245, whereby the electrical signal and power may be transmitted more smoothly.

When the first conductive pad 243 and the third conductive pad 245 are formed by the electroplating process, the uniformity of the electroplating may be improved by additionally forming the dummy conductive pads (second conductive pads 244). In addition, by forming the dummy conductive pads (the second conductive pads 244) at the same level as the level of first conductive pad 243 and the third conductive pad 245, the flatness may be increased in a chemical mechanical polishing (CMP) process performed thereafter.

The first via plugs 246 pass through the interlayer dielectric layer (ILD) 241 and the etch stop layer 242. One end of the first via plug 246 is in contact with the third conductive pad 245 and the other end is in contact with the first bonding pad 254. The first via plugs 246 are electrically coupled with the third conductive pad 245 and the first bonding pad 254. In an embodiment, the width of the first via plugs 246 in the horizontal direction may be about 0.01 μm to about 10 μm. In an embodiment, the depth of the first via plugs 246 in the vertical direction may be about 0.01 μm to about 10 μm.

The second via plugs 247 pass through the interlayer dielectric layer (ILD) 241 and the etch stop layer 242. One end of the second via plug 247 is in contact with the dummy conductive pad (the second conductive pad 244) and the other end is in contact with the dummy bonding pad (the second bonding pad 255). The second via plugs 247 do not serve to transmit the electrical signal and the power. In an embodiment, the second via plug 247 may include a dummy via plug. In an embodiment, the width of the second via plugs 247 in the horizontal direction may be about 0.01 μm to about 10 μm. In an embodiment, the depth of the second via plugs 247 in the vertical direction may be about 0.01 μm to about 10 μm.

Compared to the semiconductor chip die 100 of FIG. 1, the semiconductor chip die 200A of FIG. 2 further includes the second via plugs 247. If the volume of a metal (e.g., copper) in the interlayer dielectric layer 241 further increases, the bonding force between the metal—the metal increases more during a heat treatment to perform the hybrid bonding. Accordingly, second via plugs 247 contacting the second bonding pad 255 within the interlayer dielectric layer 241 may be additionally disposed.

The second conductive pad 244 and the second bonding pad 255 may be matched one-to-one. In an embodiment, the second bonding pad 255 may be spaced apart from the second conductive pad 244. In an embodiment, the second conductive pads 244 and the second bonding pads 255 may have the same interval as each other. In an embodiment, the second conductive pad 244 and the second bonding pad 255 may have the same shape and size as each other. In another embodiment, the second conductive pad 244 and the second bonding pad 255 may include different shapes and sizes. In an embodiment, the width of the first bonding pads 254 in the horizontal direction may be about 0.01 μm to about 10 μm. In an embodiment, the depth of the first bonding pads 254 in the vertical direction may be about 0.1 μm to about 7 μm. In an embodiment, the width of the second bonding pads 255 in the horizontal direction may be about 0.01 μm to about 10 μm. In an embodiment, the depth of the second bonding pads 255 in the vertical direction may be about 0.1 μm to about 7 μm. In an embodiment, the interval between the first bonding pads 254, between the second bonding pads 255, or between the first bonding pads 254 and the second bonding pads 255 may be less than about 30 μm.

In an embodiment, the first conductive pad 243, the second conductive pads 244, the third conductive pads 245, and the first via plugs 246 and the second via plugs 247 may include at least one of: copper, aluminum, tungsten, nickel, gold, tin, titanium, and their alloys. In another embodiment, fewer or more first conductive pads 243, second conductive pads 244, third conductive pads 245 and first via plugs 246, and second via plugs 247 may be provided.

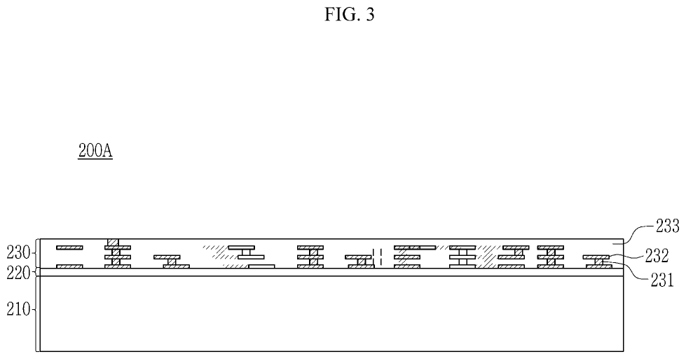

FIG. 3 to FIG. 22 are cross-sectional views showing a method for manufacturing the semiconductor chip die 200A of FIG. 2.

FIG. 3 is a cross-sectional view showing a step of forming a substrate 210, a device structure 220 on the substrate 210, and a interconnect structure 230 on the device structure 220.

Referring to FIG. 3, the semiconductor chip die 200A in which the device structure 220 is formed on the substrate 210 in the FEOL process and the interconnect structure 230 is formed on the device structure 220 in the BEOL process is provided.

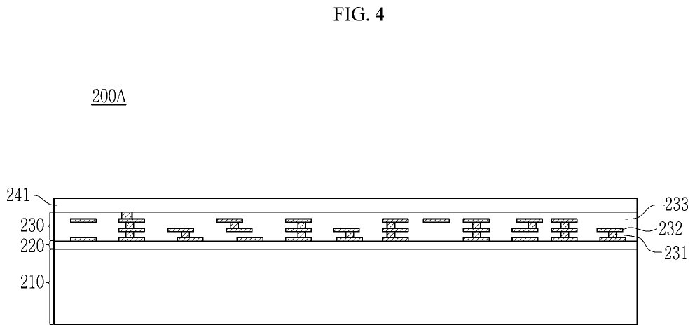

FIG. 4 to FIG. 9 are views showing steps of forming a first conductive pad 243, second conductive pads 244, and third conductive pads 245 by electroplating, following the step shown in FIG. 3.

FIG. 4 is a cross-sectional view showing a step of depositing an interlayer dielectric layer 241 on an interconnect structure 230.

Referring to FIG. 4, the interlayer dielectric layer 241 is deposited on the interconnect structure 230. In an embodiment, the interlayer dielectric layer 241 may be formed through a thermal chemical vapor deposition (CVD) (a thermal CVD) process, a plasma enhanced chemical vapor deposition (CVD) (a plasma enhanced CVD) process, or an atomic layer deposition (ALD) process. In an embodiment, the interlayer dielectric layer 241 may include a silicon oxide, a silicon nitride, a silicon oxynitride, a TEOS-forming oxide, PSG, BPSG, a low-k dielectric material, another suitable dielectric material, or a combination thereof.

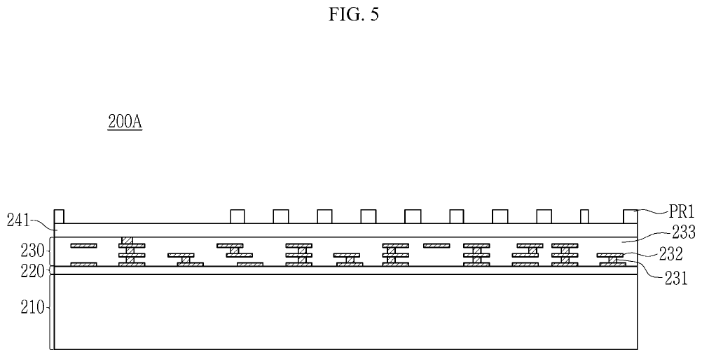

FIG. 5 is a cross-sectional view showing a step of forming a photoresist pattern PR1 by depositing a photoresist on the interlayer dielectric layer 241, and exposing and developing the photoresist.

Referring to FIG. 5, a photoresist is formed on the interlayer dielectric layer 241. In an embodiment, the photoresist may be formed through spin coating. In another embodiment, the photoresist may be formed through a sputtering process, a physical vapor deposition (PVD) process, an atomic layer deposition (ALD) process, or a chemical vapor deposition (CVD) process. In an embodiment, the photoresist may include an organic polymeric resin including a photoactive material. In another embodiment, the photoresist may include an inorganic material. Then, the photoresist pattern PR1 is formed by exposing and developing the photoresist.

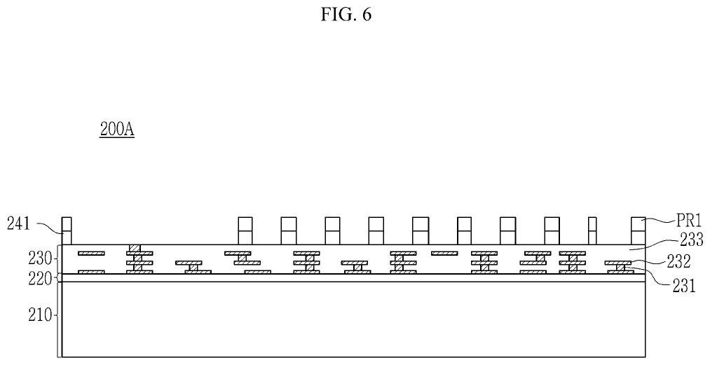

FIG. 6 is a cross-sectional view showing a step of etching the interlayer dielectric layer 241 using the photoresist pattern PR1 as an etching mask.

Referring to FIG. 6, by using the photoresist pattern PR1 as an etching mask, the rest of the interlayer dielectric layer 241 except for the portion where the first conductive pad 243, the second conductive pads 244, and the third conductive pads 245 in the interlayer dielectric layer 241 will be formed is etched.

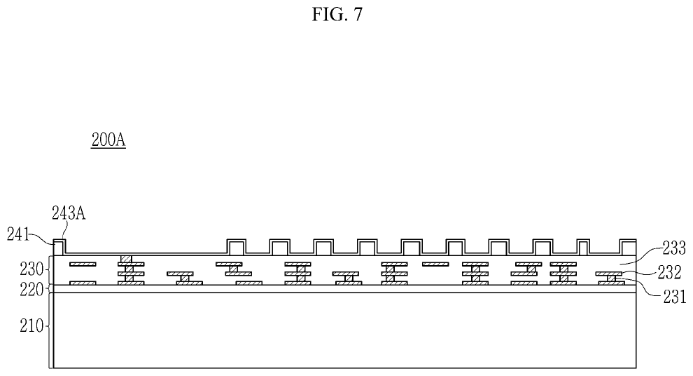

FIG. 7 is a cross-sectional view showing a step of removing the photoresist pattern PR1 and depositing a seed metal layer 243A.

Referring to FIG. 7, the photoresist pattern PR1 is removed by an ashing or etching process. Then, the seed metal layer 243A is deposited. In an embodiment, the seed metal layer 243A may include copper. In another embodiment, the seed metal layer 243A may include a conductive material capable of electroplating. In an embodiment, the seed metal layer 243A is formed by the electroless plating. In an embodiment, a cleaning process or a metal catalyst activation pretreatment process may be performed prior to the electroless plating. In another embodiment, the seed metal layer 243A is formed by the sputtering.

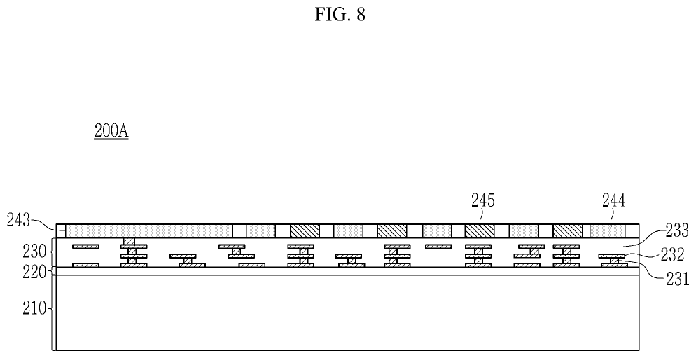

FIG. 8 is a cross-sectional view showing a step of forming first conductive pads 243, second conductive pads 244, and third conductive pads 245 by electroplating.

Referring to FIG. 8, within openings of the dielectric layer 241, the first conductive pad 243, the second conductive pads 244, and the third conductive pads 245 are formed. In an embodiment, the first conductive pad 243, the second conductive pads 244, and the third conductive pads 245 may include copper. In another embodiment, the first conductive pad 243, the second conductive pads 244, and the third conductive pads 245 may include a conductive material capable of being electroplated. In an embodiment, the first conductive pad 243, the second conductive pads 244, and the third conductive pads 245 are formed by electroplating. The first conductive pad 243, the second conductive pads 244, and the third conductive pads 245 are formed by growing a metal layer from the previously formed seed metal layer 243A by electroplating. In an embodiment, an annealing process may be performed after the first conductive pad 243, the second conductive pads 244, and the third conductive pads 245 are formed.

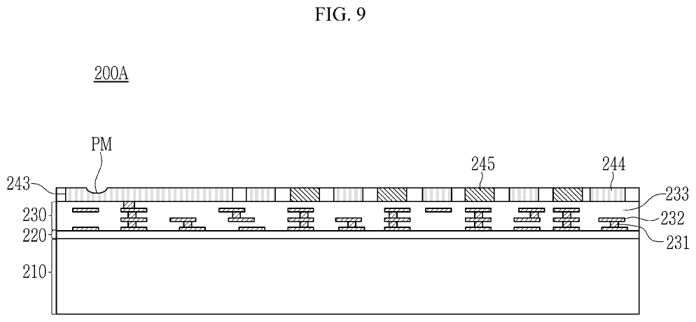

FIG. 9 is a cross-sectional view showing a step of performing an EDS test on the first conductive pad 243.

Referring to FIG. 9, the EDS test is performed by contacting a probe to the first conductive pad 243, and it is determined whether the semiconductor chip die 200A is defective. After performing the EDS test, a probe mark PM is formed on the upper surface of the first conductive pad 243.

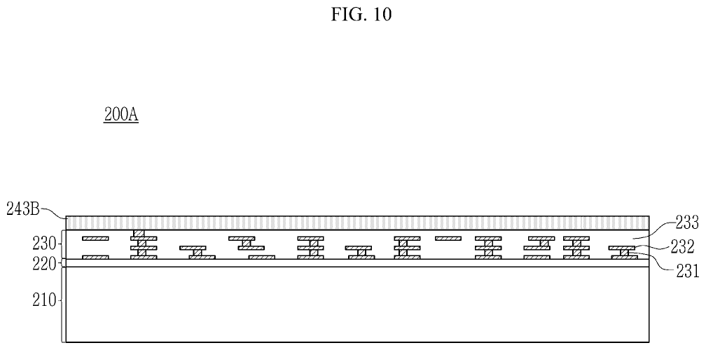

FIG. 10 to FIG. 14 are views showing steps of forming a first conductive pad 243, second conductive pads 244, and third conductive pads 245 by a thin film deposition, following the step shown in FIG. 3.

FIG. 10 is a cross-sectional view showing a step of depositing a metal layer 243B on the interconnect structure 230.

Referring to FIG. 10, the metal layer 243B is deposited on the interconnect structure 230. In an embodiment, the metal layer 243B may be formed by a physical vapor deposition (PVD) process. In an embodiment, the metal layer 243B may be formed by a sputtering process. In an embodiment, the metal layer 243B may include aluminum. In another embodiment, the metal layer 243B may include a conductive material capable of a PVD process.

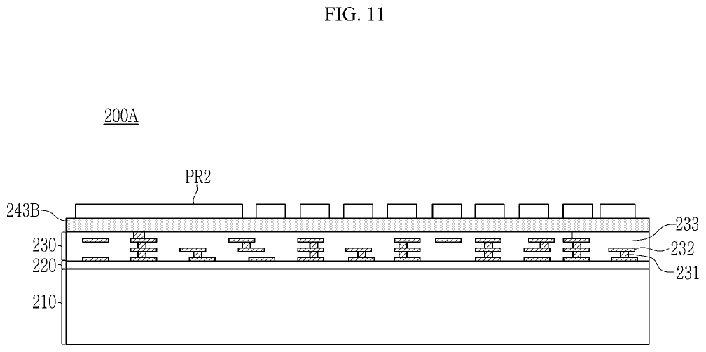

FIG. 11 is a cross-sectional view showing a step of forming a photoresist pattern PR2 by depositing a photoresist on the metal layer 243B and exposing and developing the photoresist.

Referring to FIG. 11, a photoresist is deposited on the metal layer 243B, and a photoresist pattern PR2 is formed by exposing and developing the photoresist. For the formation method and material of the photoresist, the contents described above with reference to FIG. 5 may be equally applied.

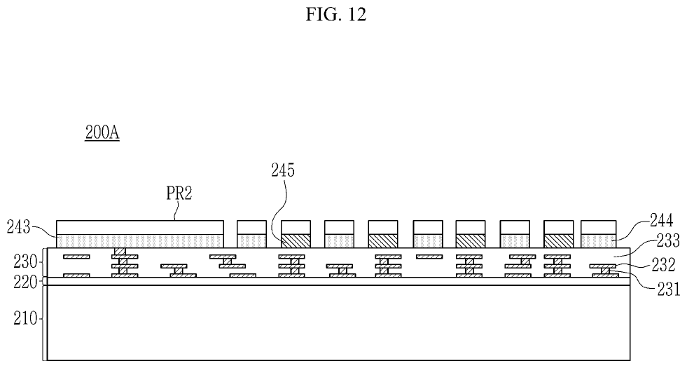

FIG. 12 is a cross-sectional view showing a step of etching the metal layer 243B by using the photoresist pattern PR2 as an etching mask.

Referring to FIG. 12, by using the photoresist pattern PR2 as an etching mask, the rest of the metal layer 243B, except for the portion where the first conductive pad 243, the second conductive pads 244, and the third conductive pads 245 will be formed, is etched.

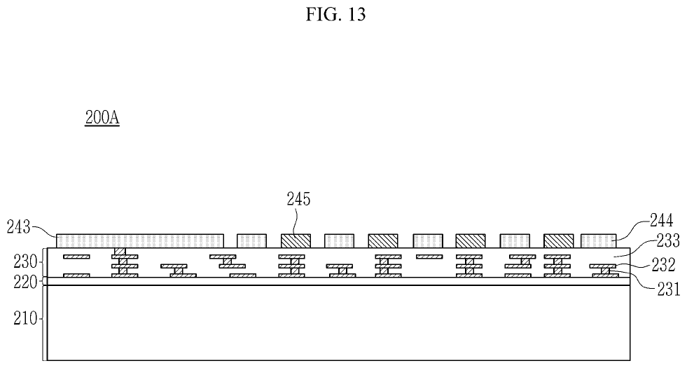

FIG. 13 is a cross-sectional view showing a step of removing the photoresist pattern PR2.

Referring to FIG. 13, the photoresist pattern PR2 is removed by performing an ashing or etching process.

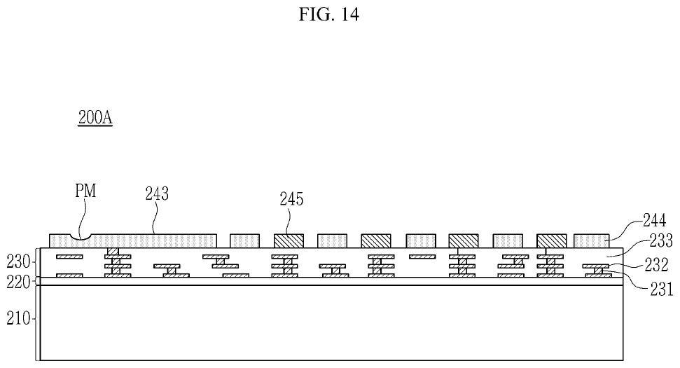

FIG. 14 is a cross-sectional view showing a step of performing an EDS test on a first conductive pad 243 as one of the steps of a semiconductor structure manufacturing method.

Referring to FIG. 14, an EDS test is performed by contacting the probe to the first conductive pad 243, and it is determined whether the semiconductor chip die 200A is defective. After performing the EDS test, a probe mark PM is formed on the upper surface of the first conductive pad 243.

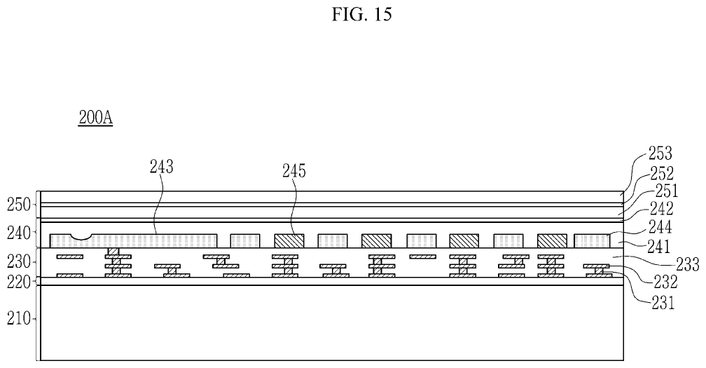

FIG. 15 is a cross-sectional view showing steps of sequentially depositing an interlayer dielectric layer 241, an etch stop layer 242, a first dielectric layer 251, a second dielectric layer 252, and a third dielectric layer 253, following the step shown in FIG. 9 or FIG. 14.

Referring to FIG. 15, an interlayer dielectric layer 241, an etch stop layer 242 on the interlayer dielectric layer 241, a first dielectric layer 251 on the etch stop layer 242, a second dielectric layer 252 on the first dielectric layer 251, and a third dielectric layer 253 on the second dielectric layer 252 are deposited. In an embodiment, the interlayer dielectric layer 241, the etch stop layer 242, the first dielectric layer 251, the second dielectric layer 252, and the third dielectric layer 253 may be formed through a thermal chemical vapor deposition (a thermal CVD) process, a plasma enhanced chemical vapor deposition (a plasma enhanced CVD) process, or an atomic layer deposition (ALD) process.

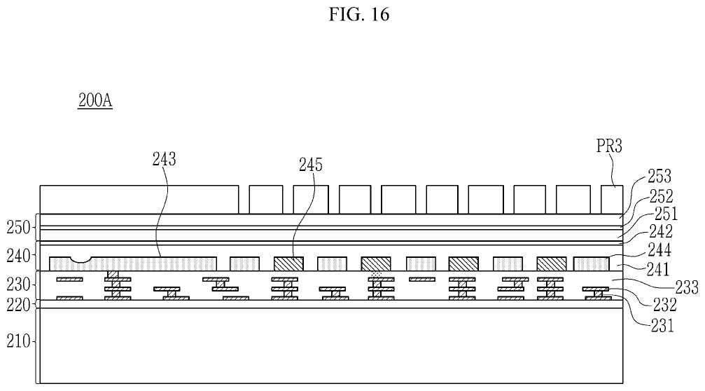

FIG. 16 is a cross-sectional view showing a step of forming a photoresist pattern PR3 by depositing a photoresist on the third dielectric layer 253 and exposing and developing the photoresist.

Referring to FIG. 16, a photoresist is deposited on the third dielectric layer 253, and a photoresist pattern PR3 is formed by exposing and developing the photoresist. For the formation method and material of the photoresist, the above-described contents described with reference to FIG. 5 may be equally applied.

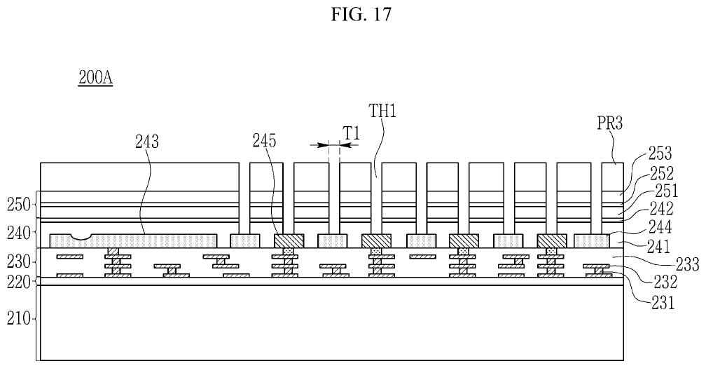

FIG. 17 is a cross-sectional view showing a step using the photoresist pattern PR3 as an etching mask to etch he interlayer dielectric layer 241, the etch stop layer 242, the first dielectric layer 251, the second dielectric layer 252, and the third dielectric layer 253.

Referring to FIG. 17, by using the photoresist pattern PR3 as an etching mask, through holes TH1 are formed in the interlayer dielectric layer 241, the etch stop layer 242, the first dielectric layer 251, the second dielectric layer 252, and the third dielectric layer 253. The through holes TH1 have a thickness T1 capable of forming a via plug. After the etching process, parts of the upper surfaces of the first conductive pad 243, the second conductive pads 244, and the third conductive pads 245 are exposed.

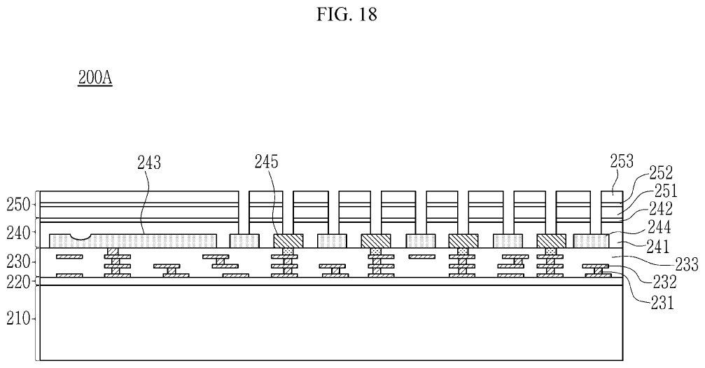

FIG. 18 is a cross-sectional view showing a step of removing the photoresist pattern PR3 as one of steps of a semiconductor structure manufacturing method.

Referring to FIG. 18, the photoresist pattern PR3 is removed by an ashing or etching process.

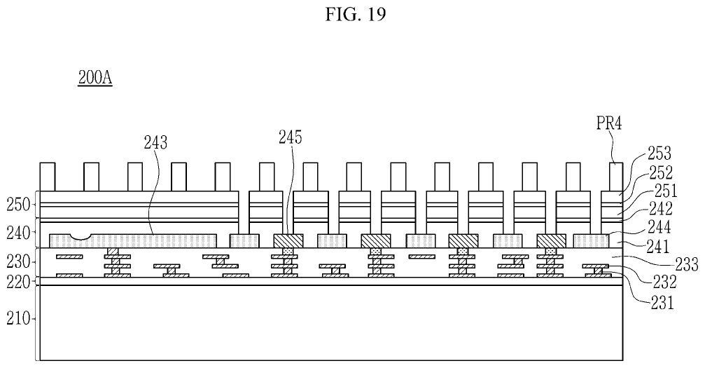

FIG. 19 is a cross-sectional view showing a step of forming a photoresist pattern PR4 by depositing a photoresist on a third dielectric layer 253 and exposing and developing the photoresist.

Referring to FIG. 19, the photoresist is deposited on the third dielectric layer 253, and the photoresist pattern PR4 is formed by exposing and developing the photoresist. For the formation method and material of the photoresist, the contents described above with reference to FIG. 5 may be equally applied.

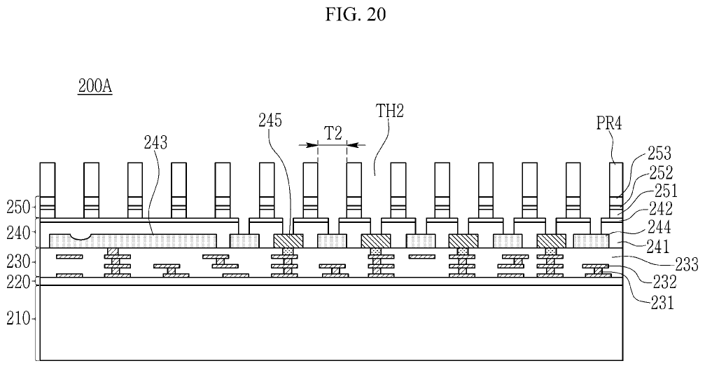

FIG. 20 is a cross-sectional view showing a step of etching the first dielectric layer 251, the second dielectric layer 252, and the third dielectric layer 253 by using the photoresist pattern PR4 as an etching mask.

Referring to FIG. 20, by using the photoresist pattern PR4 as an etching mask, the first dielectric layer 251, the second dielectric layer 252, and the third dielectric layer 253 are etched to form through holes TH2. The through holes TH2 have a thickness T2 that can form a bonding pad. After the etching process, a part of the upper surface of the etch stop layer 242 is exposed.

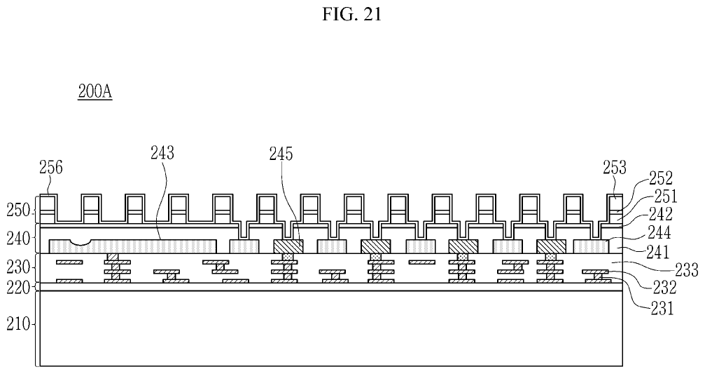

FIG. 21 is a cross-sectional view showing a step of removing the photoresist pattern and depositing a seed metal layer 256 on an exposed surface.

Referring to FIG. 21, the photoresist pattern PR4 is removed by an ashing or etching process. Then, the seed metal layer 256 is deposited. For the formation method and material of the seed metal layer 256, the contents described above with reference to FIG. 7 can be equally applied.

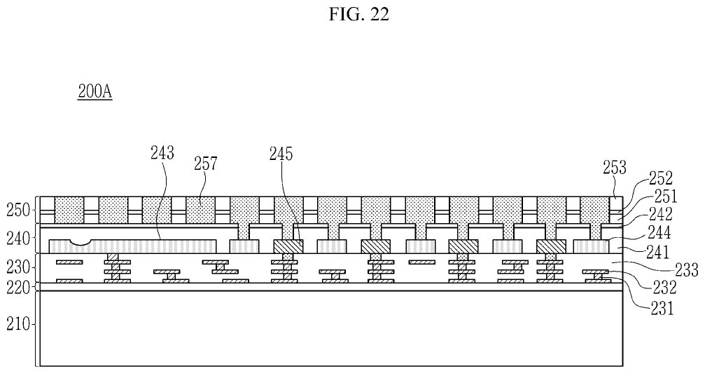

FIG. 22 is a cross-sectional view showing a step of filling the through holes TH1 and TH2 with a conductive material 257 by electroplating.

Referring to FIG. 22, the via plug and bonding pads are formed by filling the conductive material 257 in the through holes TH1 and TH2 by electroplating. The via plugs and bonding pads are formed by a dual damascene process. Specifically, the photo process and etching process for forming the via plugs are performed first (referring to FIG. 16 to FIG. 18), and the photo process and etching process for forming the bonding pads is secondarily performed (referring to FIG. 19 to FIG. 21), and then the via plugs and the bonding pads are formed by the dual damascene process according to the method of filling the conductive material 257 at once.

After this, a CMP process or mechanical grinding process is performed to planarize the upper parts of the third dielectric layer 253 and the filled conductive material 257. Hereby, the semiconductor chip die 200A of FIG. 2 is formed.

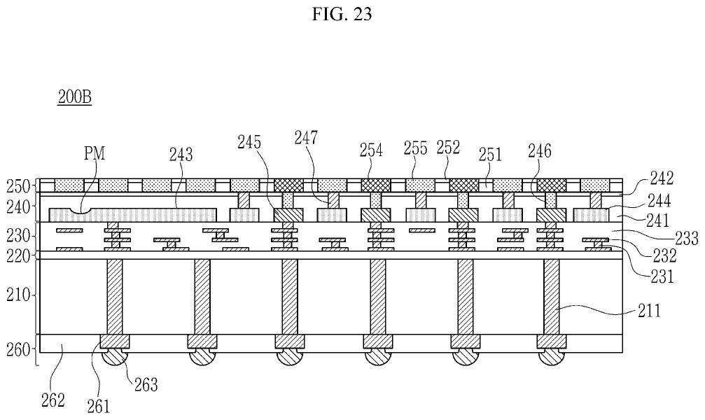

FIG. 23 is a cross-sectional view showing a semiconductor structure in which through-silicon vias (TSV) 211 are disposed in the substrate 210, and an external connection terminal structure 260 is disposed on a bottom surface of a substrate 210 in addition to a semiconductor structure of FIG. 2.

Referring to FIG. 23, the semiconductor chip die 200B may include through-silicon vias (TSV) 211 in the back side of the substrate 210. The through-silicon vias (TSV) 211 may be formed by forming holes penetrating the insulating material from the back side of the substrate 210 and filling the holes with the conducting material. In an embodiment, the holes of the through-silicon vias (TSV) 211 may be formed by deep etching. In another embodiment, the holes of the through-silicon vias (TSV) 211 may be formed by a laser. In an embodiment, the holes of the through-silicon vias (TSV) 211 may be filled with the conducting material by electroplating. In an embodiment, the through-silicon via (TSV) 211 may include at least one of: tungsten, aluminum, copper, and their alloys. In addition, a barrier layer (not shown) may be formed between the through-silicon via (TSV) 211 and the insulating material of the substrate 210. In an embodiment, the barrier layer may include at least one of: titanium, tantalum, titanium nitride, tantalum nitride, or an alloy thereof.

The semiconductor chip die 200B may include an external connection terminal structure 260 on the bottom surface of the substrate 210. The external connection terminal structure 260 may include metal pads 261, an insulation layer 262, and an external connection member 263. The metal pads 261 electrically couple the through-silicon via (TSV) 211 and the external connection member 263. In an embodiment, the metal pads 261 may include at least one of: copper, nickel, zinc, gold, silver, platinum, palladium, chromium, titanium, and alloys thereof. The insulation layer 262 may include a plurality of openings for soldering. In an embodiment, the insulation layer 262 may include a solder resist. The insulation layer 262 prevents the external connection member 263 from being short-circuited. The external connection member 263 connects the semiconductor chip die 200B to an external device. In an embodiment, the external connection member 263 may include at least one of: tin, silver, lead, nickel, copper, or an alloy thereof.

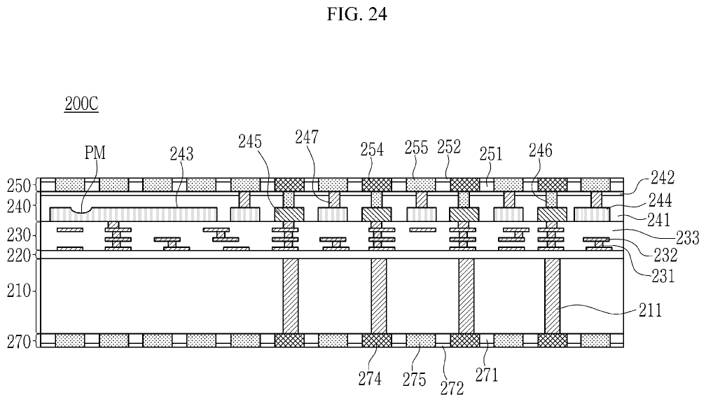

FIG. 24 is a cross-sectional view showing a semiconductor structure in which the through-silicon vias 211 are disposed in the substrate 210, and a bonding structure 270 capable of hybrid bonding to a bottom surface of the substrate 210 is disposed in addition to a semiconductor structure of FIG. 2.

Referring to FIG. 24, the semiconductor chip die 200C may include through-silicon vias (TSVs) 211 on the back side of the substrate 210. In addition, a barrier layer may be formed between the through-silicon vias (TSV) 211 and the insulating material of the substrate 210. The contents described above with reference to FIG. 23 may be equally applied to the formation method and material of the through-silicon via (TSV) 211 and the barrier layer of FIG. 24.

The semiconductor chip die 200C may include the bonding structure 270 (e.g., a back side bonding structure) on the back side of the substrate 210. The bonding structure 270 may include a fourth dielectric layer 271, a fifth dielectric layer 272, a third bonding pad 274, and a fourth bonding pad 275.

The fourth dielectric layer 271 is disposed on the bottom surface of the substrate 210. In an embodiment, the fourth dielectric layer 271 may include a silicon oxide, a TEOS-forming oxide, another suitable dielectric material, or a combination thereof.

The fifth dielectric layer 272 is disposed on the fourth dielectric layer 271. The fifth dielectric layer 272 is a layer on which a non-metal-non-metal hybrid bonding is performed with a dielectric layer of another semiconductor chip die. In an embodiment, the fifth dielectric layer 272 may include a silicon nitride. In an embodiment, the fifth dielectric layer 272 may include SiN or SiCN.

The third bonding pads 274 are disposed to pass through the fourth dielectric layer 271 and the fifth dielectric layer 272. The third bonding pads 274 are pads on which a metal-metal hybrid bonding is performed with the bonding pads of other semiconductor chip dies together with the fourth bonding pads 275, whereby electrical coupling is performed between the semiconductor chip die and the semiconductor chip die. The third bonding pad 274 is electrically coupled with the through-silicon via (TSV) 211.

The fourth bonding pads 275 are disposed to pass through the fourth dielectric layer 271 and the fifth dielectric layer 272. The fourth bonding pads 275 are disposed on the same level as the level of the third bonding pads 274. The fourth bonding pad 275 may include a dummy bonding pad. The fourth bonding pads 275 are pads on which metal-metal hybrid bonding is performed with bonding pads of other semiconductor chip dies together with third bonding pads 274, but are not related to electrical coupling between semiconductor chip dies and semiconductor chip dies. The fourth bonding pad 275 is electrically decoupled from a through-silicon via (TSV) 211 or other components.

The third bonding pad 274 or the fourth bonding pad 275 may have the same diameter as a diameter of another third bonding pad 274 or another fourth bonding pad 275. The interval (pitch) between the neighboring third bonding pads 274, the interval between the neighboring fourth bonding pads 275, or the interval between the neighboring third bonding pads 274 and fourth bonding pad 275 may be the same. In an embodiment, in a plane view, the third bonding pad 274 or the fourth bonding pad 275 may include a circle, an ellipse, a quadrangle, a polygon, and various other shapes. In an embodiment, the third bonding pad 274 and the fourth bonding pad 275 may include copper. In another embodiment, the third bonding pad 274 and the fourth bonding pad 275 may be a metallic material capable of applying hybrid bonding.

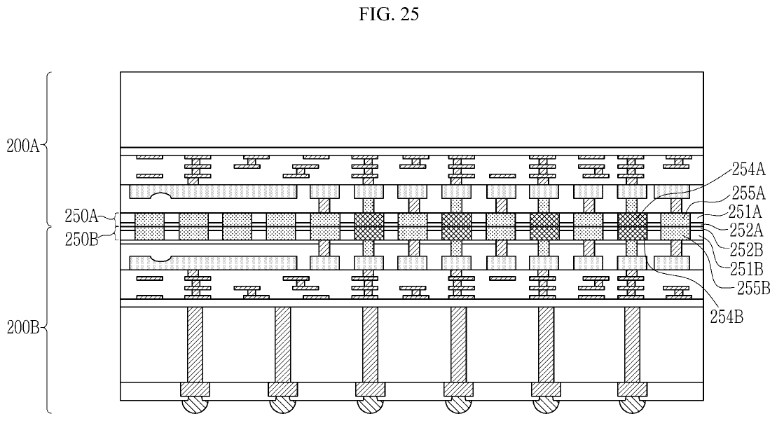

FIG. 25 is a cross-sectional view showing that a front side of a semiconductor structure FIG. 2 and the front side of the semiconductor structure of FIG. 23 are bonded by hybrid bonding.

Referring to FIG. 25, the front side of the semiconductor chip die 200A and the front side of the semiconductor chip die 200B are bonded by hybrid bonding. The first bonding pads 254A of the bonding structure 250A of the semiconductor chip die 200A and the first bonding pads 254B of the bonding structure 250B of the semiconductor chip die 200B, and the second bonding pads 255A of the bonding structure 250A and the second bonding pads 255B of the bonding structure 250B, are directly joined by metal-metal hybrid bonding. At the interface between the first bonding pad 254A and the first bonding pad 254B, and between the second bonding pad 255A and the second bonding pads 255B, metal bonding is formed by heat and pressure. The first bonding pads 254A and the first bonding pads 254B, and the second bonding pads 255A and the second bonding pads 255B, are composed of the same material, and after the hybrid bonding, the interface between the first bonding pads 254A and the first bonding pads 254B, and between the second bonding pads 255A and the second bonding pads 255B, may disappear. The semiconductor chip die 200A and the semiconductor chip die 200A may be electrically connected to each other through the first bonding pads 254A and the first bonding pads 254B, and the second bonding pads 255A and the second bonding pads 255B.

The second dielectric layer 252A of the bonding structure 250A of the semiconductor chip die 200A and the second dielectric layer 252B of the bonding structure 250B of the semiconductor chip die 200B are directly joined by non-metal-non-metal hybrid bonding. At the interface between the second dielectric layer 252A and the second dielectric layer 252B, covalent bonding is performed by heat and pressure. The second dielectric layer 252A and the second dielectric layer 252B are composed of the same material, and after the hybrid bonding, the interface between the second dielectric layer 252A and the second dielectric layer 252B may disappear.

According to embodiments, the second dielectric layer 252A may be on the first dielectric layer 251A of the bonding structure 250A of the semiconductor chip die 200A, and the second dielectric layer 252B may be on the first dielectric layer 251B of the bonding structure 250B of the semiconductor chip die 200B.

The process in which the hybrid bonding is performed is described as follows.

First, in order to facilitate the hybrid bonding, the CMP process may be performed before the hybrid bonding. In an embodiment, the surface roughness of the bonding surface of each semiconductor chip die on which the hybrid bonding is performed may be about 10 Å or less.

Then, the bonding surfaces of the bonding structure 250A of the semiconductor chip die 200A and the bonding structure 250B of the semiconductor chip die 200B are cleaned. In an embodiment, the cleaning of the bonding surface may be performed by wet cleaning. Then, the bonding surfaces of the second dielectric layer 252A of the bonding structure 250A and the second dielectric layer 252B of the bonding structure 250B are activated. In some embodiments, the bonding surface may be subjected to a surface treatment by plasma activation. Then, the semiconductor chip die 200A and the semiconductor chip die 200B are aligned for the hybrid bonding. Then, the activated bonding surface of the second dielectric layer 252A of the bonding structure 250A and the activated bonding surface of the second dielectric layer 252B of the bonding structure 250B are in contact with each other to be pre-bonded.

After this, the semiconductor chip die 200A and the semiconductor chip die 200B are hybrid bonded. First, the second dielectric layer 252A of the bonding structure 250A and the second dielectric layer 252B of the bonding structure 250B are bonded by a treatment. The treatment strengthens the bonding of the second dielectric layer 252A of the bonding structure 250A and the second dielectric layer 252B of the bonding structure 250B, which are pre-bonded. In an embodiment, the treatment may be performed at a temperature ranging from about 100° C. to about 150° C.

Next, the first bonding pads 254A of the bonding structure 250A and the first bonding pads 254B of the bonding structure 250B, and the second bonding pads 255A of the bonding structure 250A and the second bonding pads 255B of the bonding structure 250B, are bonded by annealing. In an embodiment, during the annealing, the pressure may be less than about 30 MPa. In an embodiment, the annealing may be performed at a temperature of about 100° C. to 500° C. In another embodiment, the annealing may be performed at a temperature ranging from about 300° C. to about 400° C. In an embodiment, the hybrid bonding may be performed in an inert environment, such as an environment charged with an inert gas including N2, Ar, He, or combinations thereof.

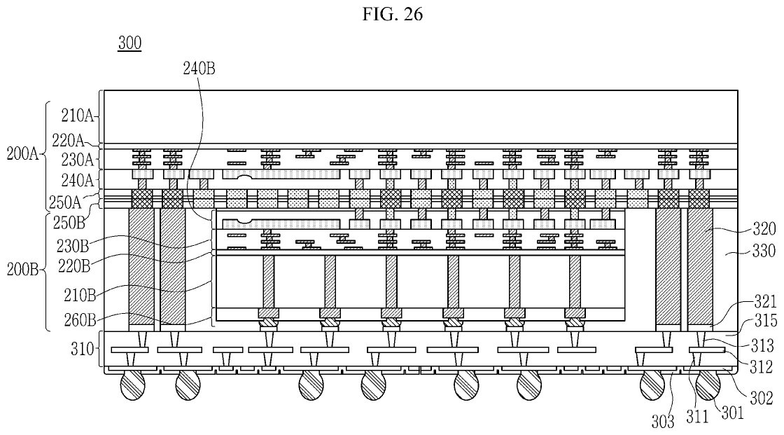

FIG. 26 is a cross-sectional view showing a Package on Package (POP) structure 300 in which a front side of one semiconductor structure and a front side of another semiconductor structure are bonded by hybrid bonding of FIG. 25.

Referring to FIG. 26, the package on package (POP) 300 includes an semiconductor chip die (semiconductor chip die 200A) and a lower semiconductor chip die (semiconductor chip die 200B) whose front sides are bonded by the hybrid bonding.

As shown in FIG. 26, the semiconductor chip die 200A may include a substrate 210A, a device structure 220A, an interconnect structure 230A, an interlayer structure 240A, and a bonding structure 250A. The semiconductor chip die 200B may include a substrate 210B, a device structure 220B, an interconnect structure 230B, an interlayer structure 240B, a bonding structure 250B, and an external connection terminal structure 260B.

In the package on package (POP) 300 according to the present disclosure, an embodiment of a case where the size of the semiconductor chip die 200A is larger than the size of the semiconductor chip die 200B is shown. Accordingly, in the semiconductor chip die 200A, the portion other than the portion coupled to the semiconductor chip die 200B may be coupled by a conductive post 320. The conductive post 320 and the semiconductor chip die 200B are disposed on a metal pad 321 disposed on an upper surface of a redistribution structure 310 including a dielectric layer 315, and a redistribution line 312 and redistribution via 311 and 313 within the dielectric layer 315, and molded by a molding material 330. An external connection terminal 301 connected to a metal pad 302 and an insulating member 303 insulating the external connection terminal 301 may be included on the bottom surface of the redistribution structure 310.

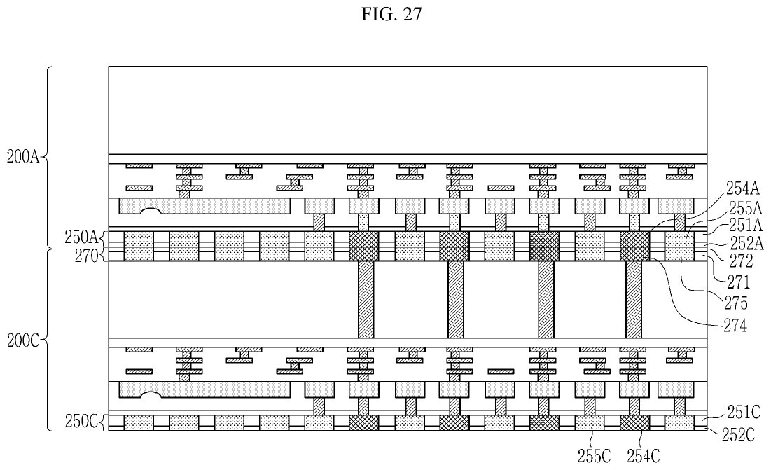

FIG. 27 is a cross-sectional view showing that a front side of a semiconductor structure of FIG. 2 and a back side of a semiconductor structure of FIG. 24 are bonded by hybrid bonding.

As shown in FIG. 27, the semiconductor chip die 200C may include, for example, a bonding structure 250C which may include a first dielectric layer 251C, a second dielectric layer 252C, first bonding pads 254C, and second bonding pads 255C.

Referring to FIG. 27, the front side of the semiconductor chip die 200A and the back side of the semiconductor chip die 200C are bonded by hybrid bonding. The first bonding pads 254A of the bonding structure 250A of the semiconductor chip die 200A and the third bonding pads 274 of the bonding structure 270 of the semiconductor chip die 200C, and the second bonding pads 255A of the bonding structure 250A and the fourth bonding pads 275 of the bonding structure 270, are directly bonded by metal-metal hybrid bonding. At interfaces between the first bonding pads 254A and the third bonding pads 274 and between the second bonding pads 255A and the fourth bonding pads 275, metal bonds are formed by heat and pressure. The first bonding pads 254A and the third bonding pads 274, and the second bonding pads 255A and the fourth bonding pads 275, are made of the same material, and after hybrid bonding, an interface between the first bonding pads 254A and the third bonding pads 274, and the second bonding pads 255A and the fourth bonding pads 275 may disappear. The semiconductor chip die 200A and the semiconductor chip die 200C may be electrically connected to each other through the first bonding pads 254A and the third bonding pads 274, and the second bonding pads 255A and the fourth bonding pads 275.

The second dielectric layer 252A of the bonding structure 250A of the semiconductor chip die 200A and the fifth dielectric layer 272 of the bonding structure 270 of the semiconductor chip die 200C are directly bonded by non-metal-non-metal hybrid bonding. At the interface between the second dielectric layer 252A and the fifth dielectric layer 272, covalent bonding is performed by heat and pressure. The second dielectric layer 252A and the fifth dielectric layer 272 are composed of the same material, and after the hybrid bonding, the interface between the second dielectric layer 252A and the fifth dielectric layer 272 may disappear.

For the process in which the hybrid bonding is performed, the contents described above with reference to FIG. 25 may be equally applied.

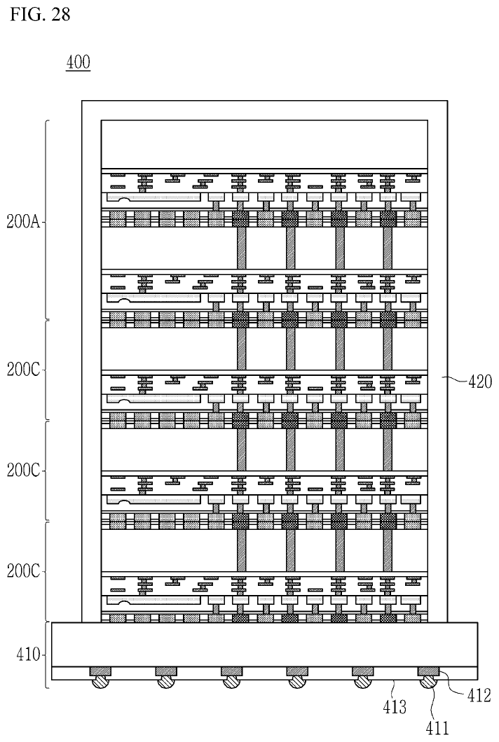

FIG. 28, as an embodiment of a semiconductor chip stacking structure in which a front side of one semiconductor structure of FIG. 27 and a back side of another semiconductor structure are bonded by hybrid bonding, is a cross-sectional view showing a high bandwidth memory (HBM) structure 400.

Referring to FIG. 28, a high band memory (HBM) 400 includes a semiconductor chip stacking structure in which the front side of the semiconductor chip die 200A and the back side of the semiconductor chip die 200C are bonded by the hybrid bonding, and then the front side of the semiconductor chip die 200C and the back side of other semiconductor chip dies 200C are bonded, and then the front side of the other semiconductor chip die 200C and the back side of the semiconductor chip dies 200C are bonded. According to the present disclosure, one semiconductor chip die 200A and three semiconductor chip dies 200C are shown, but a high-bandwidth memory (HBM; 400) including fewer or more semiconductor chip dies is included within embodiments of the present disclosure.

The semiconductor chip stacking structure of the high-bandwidth memory (HBM) 400 may be disposed on an interposer 410 and surrounded by the molding material 420. The lower portion of the interposer 410 may include an external connection terminal 411 connected to the metal pad 412 and an insulating member 413 insulating the external connection terminal.

While non-limiting example embodiments have been described above, it is to be understood that embodiments of the present disclosure are not limited to the example embodiments. Embodiments of the present disclosure are intended to cover various modifications and equivalent arrangements included within the spirit and scope of the present disclosure.

What is claimed is:

1. A semiconductor structure comprising:
an interconnect structure on a substrate;
an interlayer dielectric layer on the interconnect structure;
at least one first conductive pad within the interlayer dielectric layer and electrically coupled with the interconnect structure;
at least one second conductive pad within the interlayer dielectric layer and electrically decoupled from the interconnect structure;
at least one first via plug within the interlayer dielectric layer; and
a bonding structure on the interlayer dielectric layer and comprising at least one first bonding pad, a plurality of second bonding pads, and a bonding dielectric layer,
wherein the at least one first bonding pad is electrically coupled to the at least one first via plug,
wherein some of the plurality of second bonding pads are spaced apart from the at least one first conductive pad in a vertical direction, and
wherein others of the plurality of second bonding pads are spaced apart from the at least one second conductive pad in the vertical direction.

2. The semiconductor structure of claim 1, wherein the at least one first conductive pad comprises an electrical die sorting (EDS) test pad.

3. The semiconductor structure of claim 1, wherein the at least one first conductive pad comprises a probe mark.

4. The semiconductor structure of claim 1, wherein the at least one second conductive pad comprises a dummy conductive pad.

5. The semiconductor structure of claim 1, wherein the at least one second conductive pad is on a same level as a level of the at least one first conductive pad.

6. The semiconductor structure of claim 1, wherein each of the plurality of second bonding pads comprises a dummy bonding pad.

7. The semiconductor structure of claim 1, wherein the at least one second conductive pad is a plurality of second conductive pads, and
wherein each of the others of the plurality of second bonding pads is connected to a respective one among the plurality of second conductive pads.

8. The semiconductor structure of claim 7, wherein each of the others of the plurality of second bonding pads is spaced apart from the plurality of second conductive pads.

9. The semiconductor structure of claim 7, further comprising a second via plug between one of the plurality of second conductive pads and one of the plurality of second bonding pads.

10. The semiconductor structure of claim 1, further comprising a third conductive pad between the first via plug and the interconnect structure.

11. A semiconductor chip stacking structure comprising:
a first semiconductor chip die; and
a second semiconductor chip die bonded to the first semiconductor chip die,
wherein each of the first semiconductor chip die and the second semiconductor chip die comprises:
an interconnect structure on a substrate;
an interlayer dielectric layer on the interconnect structure;
at least one first conductive pad within the interlayer dielectric layer and electrically coupled with the interconnect structure;
at least one second conductive pad within the interlayer dielectric layer and electrically decoupled from the interconnect structure;
at least one first via plug within the interlayer dielectric layer and electrically coupled with the interconnect structure; and
a first bonding structure on the interlayer dielectric layer, the first bonding structure comprises:
a first dielectric layer;
a second dielectric layer on the first dielectric layer;
at least one first bonding pad passing through the first dielectric layer and the second dielectric layer; and
a plurality of second bonding pads passing through the first dielectric layer and the second dielectric layer,
wherein the at least one first bonding pad is electrically coupled with the at least one first via plug,
wherein some of the plurality of second bonding pads are spaced apart from the at least one first conductive pad in a vertical direction, and
wherein others of the plurality of second bonding pads are spaced apart from the at least one second conductive pad in the vertical direction.

12. The semiconductor chip stacking structure of claim 11, wherein the at least one first bonding pad of the first semiconductor chip die is directly bonded to the at least one first bonding pad of the second semiconductor chip die, and the plurality of second bonding pads of the first semiconductor chip die is directly bonded to the plurality of second bonding pads of the second semiconductor chip die.

13. The semiconductor chip stacking structure of claim 11, wherein the second dielectric layer of the first semiconductor chip die is directly bonded to the second dielectric layer of the second semiconductor chip die.

14. The semiconductor chip stacking structure of claim 11, wherein the first semiconductor chip die further comprises:
a second bonding structure on a bottom surface of the substrate of the first semiconductor chip die and comprising at least one third bonding pad, a plurality of fourth bonding pads, and a third dielectric layer; and
at least one through-silicon via (TSV) in the substrate of the first semiconductor chip die and in contact with the at least one third bonding pad.

15. The semiconductor chip stacking structure of claim 14, wherein the at least one third bonding pad is directly bonded to the at least one first bonding pad of the second semiconductor chip die, and the plurality of fourth bonding pads is directly bonded to the plurality of second bonding pads of the second semiconductor chip die.

16. The semiconductor chip stacking structure of claim 14, wherein the third dielectric layer is directly bonded to the second dielectric layer of the second semiconductor chip die.

17. A semiconductor structure manufacturing method comprising:
forming at least one test pad and at least one dummy pad on a interconnect structure on a substrate, wherein the at least one test pad is electrically coupled with the interconnect structure, and the at least one dummy pad is electrically decoupled from the interconnect structure;
depositing an interlayer dielectric layer on the at least one test pad and the at least one dummy pad;
depositing a bonding dielectric layer on the interlayer dielectric layer; and
forming at least one via plug passing through the interlayer dielectric layer and at least one first bonding pad and a plurality of second bonding pads passing through the bonding dielectric layer,
wherein the at least one first bonding pad is in contact with the at least one via plug,
wherein some of the plurality of second bonding pads are spaced apart from the at least one test pad in a vertical direction, and
wherein others of the plurality of second bonding pads are spaced apart from the at least one dummy pad in the vertical direction.

18. The semiconductor structure manufacturing method of claim 17, wherein the forming the at least one test pad and the at least one dummy pad comprises forming the at least one test pad and the at least one dummy pad by electroplating.

19. The semiconductor structure manufacturing method of claim 17, wherein the forming the at least one test pad and the at least one dummy pad comprises forming the at least one test pad and the at least one dummy pad by a physical vapor deposition (PVD) process.

20. The semiconductor structure manufacturing method of claim 17, wherein the forming the at least one via plug, the at least one first bonding pad, and the plurality of second bonding pads comprises forming the at least one via plug, the at least one first bonding pad, and the plurality of second bonding pads by a dual damascene process.
